(19) United States
(12) Patent Application Publication
(10) Pub. No.: US 2025/0285885 A1
(43) Pub. Date: Sep. 11, 2025

(54) LIQUID STORAGE APPARATUS, SEMICONDUCTOR MANUFACTURING SYSTEM, AND LIQUID REPLENISHING METHOD

(71) Applicant: Tokyo Electron Limited, Tokyo (JP)

(72) Inventor: Ryoya TOMINAGA, Iwate (JP)

(21) Appl. No.: 19/072,373

(22) Filed: Mar. 6, 2025

(30) Foreign Application Priority Data
Mar. 11, 2024 (JP) 2024-037320

(51) Int. Cl. H01L 21/67; G05D 9/12

(52) U.S. Cl. CPC H01L 21/67051; G05D 9/12

(57) ABSTRACT

A liquid storage apparatus includes: a container body storing a processing liquid for a substrate processing apparatus therein; a liquid level sensor provided in the container body, and detecting a liquid level of the processing liquid stored in the container body; a replenishment unit replenishing the processing liquid in the container body; and a control unit acquiring detection information from the liquid level sensor, and performing a processing. The liquid level sensor includes four or more detectors capable of detecting the liquid level of the processing liquid along a height direction of the container body, and the control unit sets at least three liquid level determination positions corresponding to different detectors, respectively, among the four or more detectors, and controls a replenishment of the processing liquid from the replenishment unit to the container body based on detection information of the set at least three liquid level determination positions.

### CROSS-REFERENCE TO RELATED APPLICATIONS

This application is based on and claims priority from Japanese Patent Application No. 2024-037320, filed on Mar. 11, 2024, with the Japan Patent Office, the disclosure of which is incorporated herein in its entirety by reference.

### TECHNICAL FIELD

The present disclosure relates to a liquid storage apparatus, a semiconductor manufacturing system, and a liquid replenishing method.

### BACKGROUND

Japanese Laid-Open Patent Publication No. 2003-146397 discloses a liquid storage apparatus (liquid supply apparatus) equipped with a liquid level sensor (detection unit) that detects the liquid level of a liquid stored in a container body (recharge tank). The liquid level sensor is configured to detect two liquid levels of a liquid, including the lowest liquid level and the highest liquid level.

Japanese Laid-Open Patent Publication No. 2008-522036 discloses a system, which stores a liquid (CVD precursor) in a container body (precursor storage tank) and supplies the vapor of the liquid to a semiconductor manufacturing apparatus while detecting the liquid level of the liquid using a liquid level sensor (level detection unit). The liquid level sensor is also configured to detect liquid levels of two set points (first and second set points).

### SUMMARY

According to an aspect of the present disclosure, a liquid storage apparatus includes: a container body storing a processing liquid for a substrate processing apparatus therein; a liquid level sensor provided in the container body, and detecting a liquid level of the processing liquid stored in the container body; a replenishment unit replenishing the processing liquid in the container body; and a control unit acquiring detection information from the liquid level sensor, and performing a processing. The liquid level sensor includes four or more detectors capable of detecting the liquid level of the processing liquid along a height direction of the container body, and the control unit sets at least three liquid level determination positions corresponding to different detectors, respectively, among the four or more detectors, and controls a replenishment of the processing liquid from the replenishment unit to the container body based on detection information of the set at least three liquid level determination positions.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a semiconductor manufacturing system including a liquid storage apparatus according to a first embodiment.

FIG. 2A is a graph illustrating a relationship between the volume of a liquid stored in a container body and an output value of a liquid level sensor. FIG. 2B is a graph illustrating the shift of a liquid level determination position set for each detector.

FIG. 3A is a cross-sectional view illustrating a state where a level of the container body is lowered. FIG. 3B is a cross-sectional view illustrating a state where the container body is replenished with a liquid.

FIG. 4 is a block diagram illustrating an example of functional blocks provided in a controller.

FIG. 5 is a flowchart illustrating a liquid supplying method and a liquid replenishing method in a semiconductor manufacturing system.

FIG. 6 is a flowchart illustrating a position correction method for correcting a liquid level determination position.

FIG. 7 is a view illustrating an example of a semiconductor manufacturing system 1 including a liquid storage apparatus 10 according to a second embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure are described with reference to the drawings. In each drawing, the same components are denoted by the same reference numeral, and overlapping descriptions thereof may be omitted.

### First Embodiment

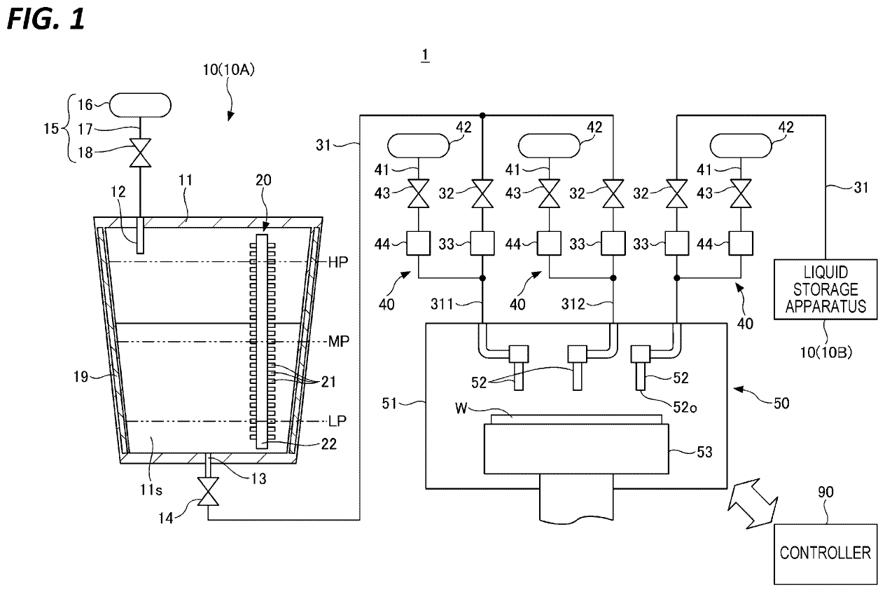

FIG. 1 is a view illustrating an example of a semiconductor manufacturing system 1 including a liquid storage apparatus 10 according to a first embodiment. As illustrated in FIG. 1, the semiconductor manufacturing system 1 is configured such that a processing liquid is supplied from the liquid storage apparatus 10 to a substrate processing apparatus 50, and a substrate processing is performed on a substrate W of the substrate processing apparatus 50 using the processing liquid. The type of substrate processing performed by the substrate processing apparatus 50 is not particularly limited, and includes, for example, a deposition process, an etching, a modification process, a stripping process, a rinsing process, and a cleaning process.

The processing liquid may be appropriately selected according to, for example, the contents of the substrate processing and the film type of the substrate W to be processed. For example, when the substrate processing is a cleaning process to clean the surface of the substrate W, a chemical liquid for cleaning the substrate W or pure water for rinsing the surface of the substrate W is applied as the processing liquid. In this case, the chemical liquid may be, for example, SPM, which is a mixture of sulfuric acid and hydrogen peroxide, APM, which is a mixture of ammonia and hydrogen peroxide, DHF, which is a mixture of hydrofluoric acid and pure water, or HPM, which is a mixture of hydrochloric acid and hydrogen peroxide. The pure water may be, for example, ultrapure water such as de-ionized water (DIW) from which ionic components have been removed. In the descriptions herein below, the processing liquid may be referred to simply as a liquid.

In the first embodiment, descriptions are made on an example of the semiconductor manufacturing system 1 that performs the cleaning process as the substrate processing. For example, the semiconductor manufacturing system 1 includes the liquid storage apparatus 10 that stores the cleaning liquid, a supply network 30 that supplies the liquid of the liquid storage apparatus 10, and the substrate processing apparatus 50 that actually performs the substrate processing. Further, the semiconductor manufacturing system 1 includes a controller 90 that manages the entire system and controls each component of the system.

The liquid storage apparatus 10 is configured to temporarily store an appropriate amount of liquid, and supply (or discharge) the liquid. For example, the liquid storage apparatus 10 includes a container body 11, an inlet port 12 that allows the flow of the liquid into the container body 11, an outlet port 13 that allows the flow of the liquid out of the container body 11, and an opening/closing valve 14 provided at the outlet port 13 (or a supply path 31 connected to the outlet port 13).

Further, the liquid storage apparatus 10 includes a replenishment unit 15 that replenishes the liquid in the container body 11, at the upstream side relative to the container body 11. The replenishment unit 15 includes, for example, a replenishment source 16 of the liquid, an inflow path 17, and an opening/closing valve 18, which are provided separately from the container body 11. The replenishment source 16 may be, for example, a mother tank of a liquid supplied from another supply source, or a liquid generating apparatus that generates a liquid. The liquid generating apparatus may be any of various apparatuses that, for example, distill a liquid, mix (add) an appropriate substance with (to) a liquid, filter a liquid, or extract a liquid. The opening/closing valve 18 opens and closes the flow channel of the inflow path 17 based on the control by the controller 90. The replenishment unit 15 discharges the liquid from the replenishment source 16 to the inflow path 17 in a state where the opening/closing valve 18 is opened, and replenishes the container body 11 with the liquid through the inlet port 12.

The container body 11 is formed, for example, in the shape of an inverted conical trapezoid tapered from the ceiling to the bottom thereof. A storage space 11s of the liquid is formed inside the container body 11 to conform to the shape of the container body 11. The size (volume) of the storage space 11s may be set according to, for example, the amount of liquid necessary for the cleaning process. The shape of the container body 11 is not particularly limited, and may be, for example, a cylindrical shape or a rectangular cylindrical shape having a constant cross-sectional area in the vertical direction.

The inlet port 12 is provided at the ceiling of the container body 11, and the outlet port 13 is provided at the bottom of the container body 11. The inlet port 12 is connected to the inflow path 17 of the replenishment unit 15, and protrudes slightly from the ceiling into the storage space 11s. The inlet port 12 allows the liquid of the replenishment unit 15 to flow into the storage space 11s from the inlet at the lower end thereof. Further, in order to reduce, for example, the turbulence of the liquid in the storage space 11s, for example, the inlet port 12 may protrude even to the vicinity of the bottom of the container body 11, and discharge the liquid from the inlet at the lower end thereof. Meanwhile, the outlet port 13 is provided substantially at the center of the bottom of the container body 11. The liquid storage apparatus 10 discharges the liquid to the supply network 30, using the weight of the liquid itself (pressure) stored in the storage space 11s. Without being limited to this configuration, the semiconductor manufacturing system 1 may be configured such that a pump or the like is provided in the supply network 30 to pressure-feed the liquid of the container body 11.

Further, the liquid storage apparatus 10 according to the first embodiment includes a heating unit 19 that heats the liquid stored in the container body 11. In the illustrated example, the heating unit 19 is provided inside the peripheral wall of the container body 11. However, the installation location of the heating unit 19 is not limited thereto, and the heating unit 19 may be provided at the bottom, the ceiling, or the outside of the container body 11. The heating unit 19 is connected to the controller 90 via a driver (not illustrated), and heats the liquid of the container body 11 to a target temperature in the manner that a supplied power in the driver is controlled according to the target temperature instructed by the controller 90. The liquid storage apparatus 10 may include a temperature sensor (not illustrated) in the container body 11 to provide a feedback on the actual temperature of the liquid. The configuration of the heating unit 19 is not particularly limited, and for example, an electric heating wire provided inside the container body 11 or a sheet heater covering the outside of the container body 11 may be applied.

Further, the liquid storage apparatus 10 includes a liquid level sensor 20 that detects the liquid level of the liquid stored in the storage space 11s of the container body 11. The configuration of the liquid level sensor 20 is described in detail herein later.

The supply network 30 includes a supply path 31 of the liquid, an opening/closing valve 32, and a flow rate controller 33. In the supply path 31 of the supply network 30, for example, branching sections or merging sections are formed according to the configuration of the substrate processing apparatus 50. For example, in the example of FIG. 1, the substrate processing apparatus 50 includes a plurality of nozzles 52, and the supply path 31 branches into a plurality of branch paths 311 and 312 from midway positions thereof to supply appropriate liquids to the plurality of nozzles 52, respectively. The supply network 30 includes the opening/closing valve 32 and the flow rate controller 33 in each of the plurality of branch paths 311 and 312.

Further, the supply network 30 includes gas supply units 40 in the plurality of branch paths 311 and 312, respectively, to supply an inert gas such as nitrogen (N₂) gas to the substrate processing apparatus 50. The gas supply units 40 include gas supply paths 41 connected to the plurality of branch paths 311 and 312, respectively. Further, each gas supply unit 40 is provided with, for example, a gas tank 42 storing the inert gas, an opening/closing valve 43, and a flow rate controller 44 on each gas supply path 41. The gas supply units 40 supply the inert gas to the substrate processing apparatus 50 through the gas supply paths 41 and the branch paths 311 and 312, in order to purge residual liquid in the flow paths of the branch paths 311 and 312 or in the substrate processing apparatus 50.

Without being limited to the configuration where the supply network 30 supplies the liquid from one liquid storage apparatus 10 to one substrate processing apparatus 50, the supply network 30 may be configured to supply the liquid from a plurality of liquid storage apparatuses 10 to one substrate processing apparatus 50. FIG. 1 illustrates an example of a configuration where a first liquid (e.g., SPM) is supplied from a first liquid storage apparatus 10A, and a second liquid (e.g., DIW) is supplied from a second liquid storage apparatus 10B. Further, the supply network 30 may be configured to supply the liquid from one liquid storage apparatus 10 to a plurality of substrate processing apparatuses 50.

The substrate processing apparatus 50 includes a processing container 51 that accommodates the substrate W, a plurality of nozzles 52 provided inside the processing container 51, and a substrate support unit 53 that supports the substrate W in the processing container 51.

Each nozzle 52 includes a protruding portion that extends vertically in the processing container 51, and ejects the liquid from an outlet 520 of the protruding portion toward the substrate W. Further, the nozzles 52 are movable in the processing container 51 by a moving mechanism (not illustrated). For example, each nozzle 52 is configured to move between an ejection position at the center of the substrate support unit 53 (substrate W) and a standby position radially outward from the substrate support unit 53, based on the control by the controller 90.

The plurality of nozzles 52 are connected to the branch paths 311 and 312, respectively, leading to the first liquid storage apparatus 10A, and connected to the supply path 31 leading to the second liquid storage apparatus 10B. Thus, each nozzle 52 may eject the liquid supplied from the paths connected thereto, from the outlet 520 to supply the liquid to the surface of the substrate W.

The substrate support unit 53 places the substrate W on the upper surface thereof. In order to hold the substrate W placed on the upper surface, the substrate support unit 53 may include securing means such as electrostatic adsorption, suction adsorption, and a mechanical lock. The substrate support unit 53 may be configured to be rotatable around the center of the upper surface thereof in the processing container 51 by a rotation mechanism (not illustrated). For example, the substrate processing apparatus 50 supplies the liquid from the nozzles 52 positioned at the center of or above the substrate W while rotating the substrate W by the substrate support unit 53. Thus, the liquid ejected onto the substrate W spreads across the substrate W outwardly in the radial direction while wetting the substrate W due to the centrifugal force of the substrate W, so that the entire surface of the substrate W may be immersed with the liquid.

The controller 90 of the semiconductor manufacturing system 1 may be a computer including, for example, a processor, a memory, an input/output interface, and a communication interface (not illustrated). The processor may be any one of, for example, a central processing unit (CPU), a graphics processing unit (GPU), an application specific integrated circuit (ASIC), a field-programmable gate array (FPGA), and a circuit including a plurality of discrete semiconductors, or an electronic circuit, which is a combination thereof, and executes and processes programs stored in the memory. The memory includes a main storage device including, for example, a semiconductor memory, and an auxiliary storage device including, for example, a disk, a drive, and a semiconductor memory (flash memory).

The controller 90 of the semiconductor manufacturing system 1 controls the operations of the liquid storage apparatus 10, the supply network 30, and the substrate processing apparatus 50 to supply the liquid and perform the substrate processing on the substrate W. At this time, the controller 90 acquires detection information from the liquid level sensor 20 of the liquid storage apparatus 10 to manage the liquid stored in the container body 11 and perform, for example, the discharge or inflow (replenishment) of the liquid. In the present embodiment, descriptions are made on an example where the controller 90 of the semiconductor manufacturing system 1 controls each component of the liquid storage apparatus 10. However, the semiconductor manufacturing system 1 may include a control unit (not illustrated) dedicated for the liquid storage apparatus 10, and control each component of the liquid storage apparatus 10 by the control unit receiving an instruction from the controller 90.

The liquid level sensor 20 of the liquid storage apparatus 10 is provided in the storage space 11s of the container body 11, and extends in a straight line shape along the height direction (vertical direction). The liquid level sensor 20 includes a plurality of detectors 21 (e.g., 25 detectors) at different positions along the height direction, and detects the presence or absence of the liquid level of the liquid at each detector 21. As for the liquid level sensor 20, a float-type level sensor may be applied, in which floats are arranged as the detectors 21 at equal intervals from each other with respect to a frame 22 extending in the height direction. For example, the detectors 21 are configured with, for example, magnets, and open and close a magnet switch by floating up due to the buoyancy of the liquid and descending when there is no liquid. The liquid level sensor 20 configured as described above may detect the liquid level in the container body 11 in steps according to the number of detectors 21. The type of the liquid level sensor 20 is not limited to the float-type liquid level sensor, but, for example, an optical type, a capacitance type, an electrode type, or a pressure (differential pressure) type may be applied.

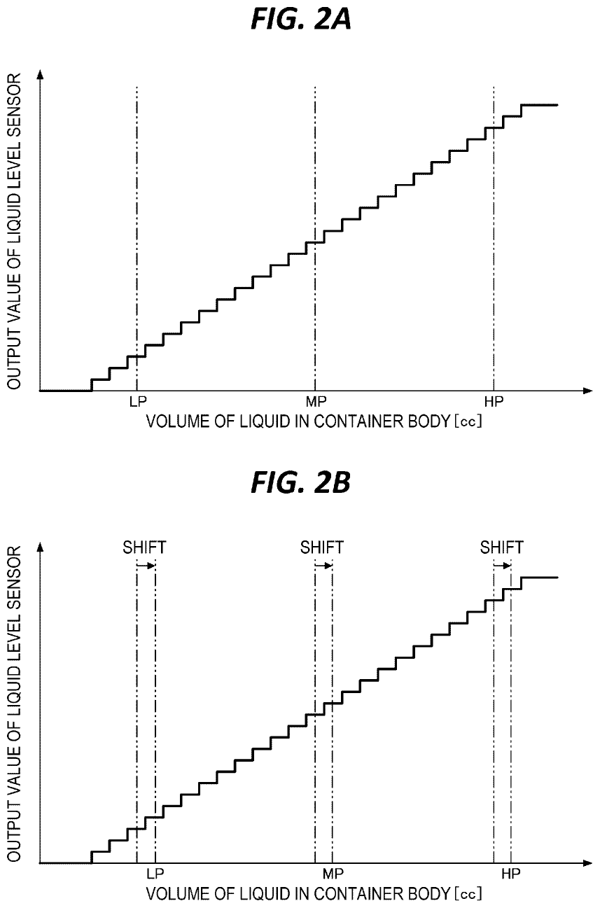

FIG. 2A is a graph illustrating a relationship between the volume of the liquid stored in the container body 11 and an output value of the liquid level sensor 20. FIG. 2B is a graph illustrating the shift of a liquid level determination position set for each detector 21. Since the detectors 21 of the liquid level sensor 20 are arranged at equal intervals along the height direction, the liquid level sensor 20 may output an output value proportional in steps with respect to the volume of the liquid in the container body 11, as illustrated in FIG. 2A. The controller 90 may have information, in advance, in which the output value of the liquid level sensor 20 is associated with the volume of the liquid (the amount of liquid) (e.g., map information), and may recognize the volume of the liquid in the container body 11 based on the output value of the liquid level sensor 20 during the operation.

The number of detectors 21 of the liquid level sensor 20 is not limited to 25, and may be less or more than 25. However, it is assumed that when the number of liquid level determination positions to be described herein later is “n,” the liquid level sensor 20 includes at least an n+1 number of detectors 21. In the first embodiment, three liquid level determination positions are set. Thus, the liquid level sensor 20 may include four or more detectors 21 along the height direction of the container body 11.

As illustrated in FIGS. 1 and 2A, the controller 90 sets at least three liquid level determination positions for the plurality of detectors 21 of the liquid level sensor 20 (25 detectors), and detects the presence or absence of the liquid level at the set liquid level determination positions. The three liquid level determination positions include a highest position HP, a middle position MP, and a lowest position LP in an order from the vertical upper side to the vertical lower side.

The highest position HP is information indicating a storage limit position when the liquid is stored in the container body 11. When the liquid is stored exceeding the highest position HP, the controller 90 stops the supply of the liquid to the container body 11 by reporting, for example, a warning or stopping the operation of the system.

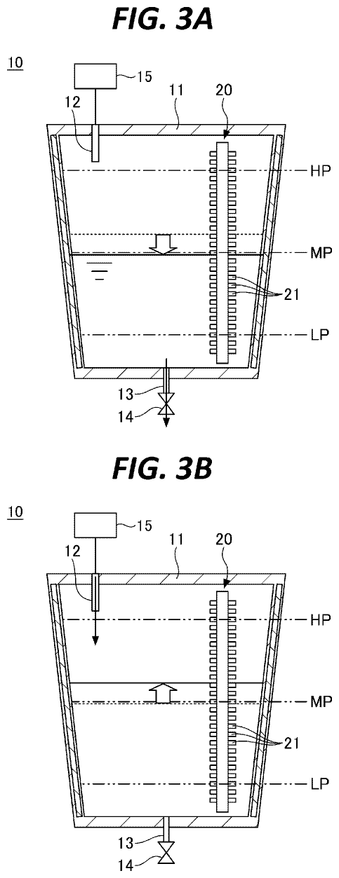

The middle position MP is information indicating a determination threshold value for determining the replenishment of the liquid by the replenishment unit 15. Hereinafter, the control based on the middle position MP, which is the liquid level determination position, is described with reference to FIGS. 3A and 3B. FIG. 3A is a view illustrating a state where the liquid level of the liquid in the container body 11 becomes lower than the middle position MP. FIG. 3B is a view illustrating a state where the container body 11 is replenished with the liquid from the replenishment unit 15.

As the liquid storage apparatus 10 supplies the liquid from the container body 11 to the substrate processing apparatus 50 during the substrate processing, the liquid level of the liquid in the container body 11 is lowered. The controller 90 regularly detects the liquid level of the liquid in the container body 11 by the liquid level sensor 20, and when it is determined that the liquid level becomes lower than the middle position MP, the controller 90 starts replenishing the liquid in the container body 11 from the replenishment unit 15. For example, when the replenishment of the liquid in a specific amount from the replenishment unit 15 is repeated, and it is determined that the liquid level exceeds the middle position MP, the liquid storage apparatus 10 stops the replenishment of the liquid by the replenishment unit 15. Alternatively, the liquid storage apparatus 10 may replenish the container body 11 with the liquid in an amount sufficiently exceeding the middle position MP (a specific amount of liquid) all at once from the replenishment unit 15.

The lowest position LP is information indicating a supply limit position when the liquid is supplied from the container body 11 to the substrate processing apparatus 50. When the liquid is discharged to become lower than the lowest position LP, the controller 90 stops the supply of the liquid from the container body 11 by reporting, for example, a warning or stopping the operation of the system. The lowest position LP may be set to a position with a certain height from the bottom of the container body 11, to ensure the amount of liquid used for one substrate processing. Thus, without immediately stopping the substrate processing when the liquid falls below the lowest position LP, the controller 90 may stop the supply of the liquid after the substrate processing is completed.

Further, without being limited to setting the three liquid level determination positions, the controller 90 may set four or more liquid level determination positions. For example, the controller 90 may set two positions (a replenishment start position for determining the start of the replenishment of liquid by the replenishment unit 15 and a replenishment stop position for determining the stop of the replenishment of liquid by the replenishment unit 15) as middle positions MP, in addition to the highest position HP and the lowest position LP,

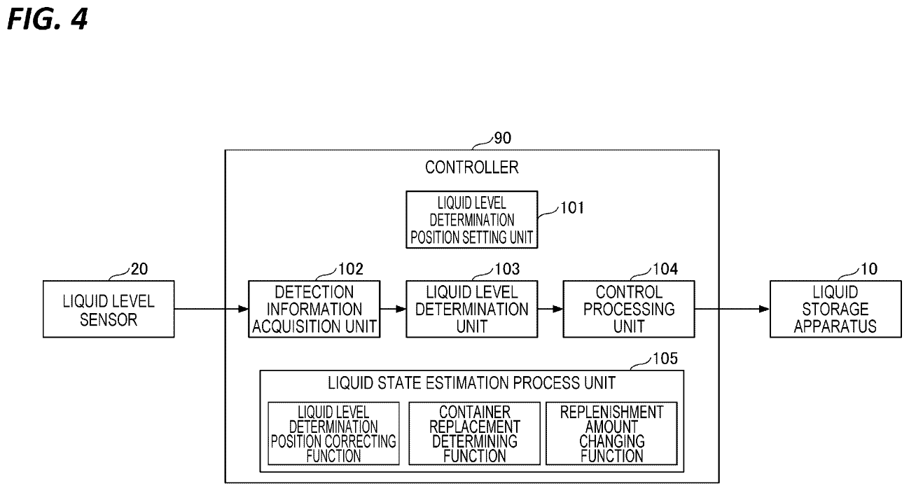

FIG. 4 is a block diagram illustrating functional blocks of the controller 90. The controller 90 causes the processor to execute the programs stored in the memory, to form functional units that process the detection information of the liquid level sensor 20 of the liquid storage apparatus 10, as illustrated in FIG. 4. For example, the controller 90 is provided with, therein, a liquid level determination position setting unit 101, a detection information acquisition unit 102, a liquid level determination unit 103, a control processing unit 104, and a liquid state estimation process unit 105.

The liquid level determination position setting unit 101 sets the liquid level determination positions of the liquid in the container body 11, automatically by the controller 90 or by a user of the semiconductor manufacturing system 1. For example, the liquid level determination position setting unit 101 sets each liquid level determination position by displaying setting screen information for setting the liquid level on a monitor (not illustrated) or the like of the controller 90, and allowing the user to operate the setting screen information.

Alternatively, the liquid level determination position setting unit 101 may adjust the liquid level determination positions (e.g., the middle position MP) based on the contents of the substrate processing of the substrate processing apparatus 50. The liquid level determination position setting unit 101 calculates the consumption of the liquid used for the substrate processing according to, for example, a recipe for the substrate processing stored in the memory, and sets the storage amount of liquid to be stored in the container body 11 during the substrate processing based on the calculated consumption of the liquid, that is, the middle position MP. For example, the liquid level determination position setting unit 101 may raise the middle position MP when the consumption of the liquid is large, and lower the middle position MP when the consumption of the liquid is small.

The detection information acquisition unit 102 acquires the detection information of the liquid level sensor 20 periodically or at appropriate timings, and stores the acquired detection information in the memory. In the memory, the information on the liquid level from the liquid level sensor 20 may be stored in association with information such as detection timings.

The liquid level determination unit 103 compares the acquired detection information of the liquid level (actual liquid level of the liquid stored in the container body 11) with each preset liquid level determination position, to determine the state of the liquid level. For example, the liquid level determination unit 103 determines whether the actual liquid level is equal to or higher than, or lower than the middle position MP.

The control processing unit 104 controls the operation of the liquid storage apparatus 10 based on, for example, the status of the substrate processing in the substrate processing apparatus 50 and the result of the determination by the liquid level determination unit 103. For example, the control processing unit 104 opens the opening/closing valve 14 with the start of the substrate processing to supply the liquid to the substrate processing apparatus 50, and closes the opening/closing valve 14 with the end of the substrate processing to stop the supply of the liquid to the substrate processing apparatus 50.

When the actual liquid level becomes lower than the middle position MP, the control processing unit 104 replenishes the liquid in the container body 11 from the replenishment unit 15. The replenishment of the liquid from the replenishment unit 15 may be performed immediately during the substrate processing, or may be performed after waiting for the end of the substrate processing. For example, when the temperature of the liquid is being adjusted by the heating unit 19, the liquid storage apparatus 10 sets the timing for supplying the liquid to a timing after the end of the substrate processing. Thus, the temperature of the liquid in the container body 11 may be suppressed from varying during the substrate processing due to the replenishment.

The liquid state estimation process unit 105 is a functional unit that automatically performs, for example, the adjustment of the liquid level determination position, the adjustment of a replenishment amount of the liquid replenished by the replenishment unit 15, and the request for replacing the container body 11 according to various statuses of the liquid storage apparatus 10 or the substrate processing apparatus 50. The statuses requiring the adjustment of the liquid level determination position include, for example, statuses (1) and (2) below.

(1) A thermal expansion occurs in the liquid according to temperatures.

(2) A precipitate is deposited in the container body 11.

Status (1) is, for example, a status in which the liquid in the container body 11 is heated (adjusted to the target temperature) by the heating unit 19. The liquid has its inherent thermal expansion coefficient, and expands according to the amount of heat received from the heating unit 19 and the thermal expansion coefficient. Thus, the liquid state estimation process unit 105 performs a process of optimizing (adjusting) the liquid level determination position according to the target temperature of the container body 11 (the heating unit 19), using the thermal expansion coefficient of the liquid as a factor. For example, when the liquid of the container body 11 expands so that the detector 21 corresponding to the middle position MP deviates, the liquid state estimation process unit 105 performs a process of shifting the detector 21 of the middle position MP to another detector 21 according to the expansion of the liquid. In this case, as illustrated in FIG. 2B, the liquid state estimation process unit 105 may shift the highest position HP and/or the lowest position LP, in addition to the middle position MP, in an integrated manner as illustrated in FIG. 2B.

Status (2) is, for example, a status in which a precipitate is deposited in the container body 11 as the substrate processing is performed multiple times, and the replenishment of the liquid in the container body 11 is repeated, when impurities or the like that easily precipitate are mixed in the liquid. The amount of precipitate may be estimated by monitoring the cumulative replenishment amount of liquid supplied to the container body 11 and/or the cumulative consumption of the liquid used in the substrate processing. For example, the liquid state estimation process unit 105 continuously stores the cumulative replenishment amount and the cumulative consumption to estimate the liquid level of the container body 11, and estimate the amount of precipitate based on the state of deviation between the estimated liquid level and the actual liquid level (current liquid level). Alternatively, the liquid state estimation process unit 105 may perform, for example, experiments or simulations to obtain a function or map information, which associates the cumulative replenishment amount of liquid and the amount of precipitate with each other, and estimate the amount of precipitate from the cumulative replenishment amount.

The liquid state estimation process unit 105 may perform a process of shifting each liquid level determination position (the highest position HP, the middle position MP, and the lowest position LP), based on the estimated amount of precipitate. For example, when the corresponding position between each detector 21 of the liquid level sensor 20 and each liquid level determination position deviates by one step as the liquid level rises due to the precipitate, the liquid state estimation process unit 105 adjusts each liquid level determination position by one step. Alternatively, when the amount of precipitate in the container body 11 increases, the liquid state estimation process unit 105 may request the user to replace the container body 11 through a user interface such as the monitor of the controller 90.

Further, the liquid state estimation process unit 105 may perform a process of monitoring the liquid level of the liquid by the liquid level sensor 20 during the replenishment of the liquid from the replenishment unit 15, and changing the replenishment amount of liquid replenished by the replenishment unit 15. For example, when replenishing the liquid, the current liquid level relative to a target liquid level may be identified from the detection information of each detector 21 of the liquid level sensor 20, and therefore, the status of the liquid replenishment may be substantially estimated. Thus, the liquid state estimation process unit 105 may increase the replenishment amount in the initial stage of the liquid replenishment from the replenishment unit 15, and decrease the replenishment amount when the liquid level reaches the vicinity of the target liquid level. As a result, the liquid storage apparatus 10 may reduce the time for the liquid replenishment, suppress, for example, the fluctuation of the liquid level after the replenishment, and improve the efficiency of the entire operation including the substrate processing.

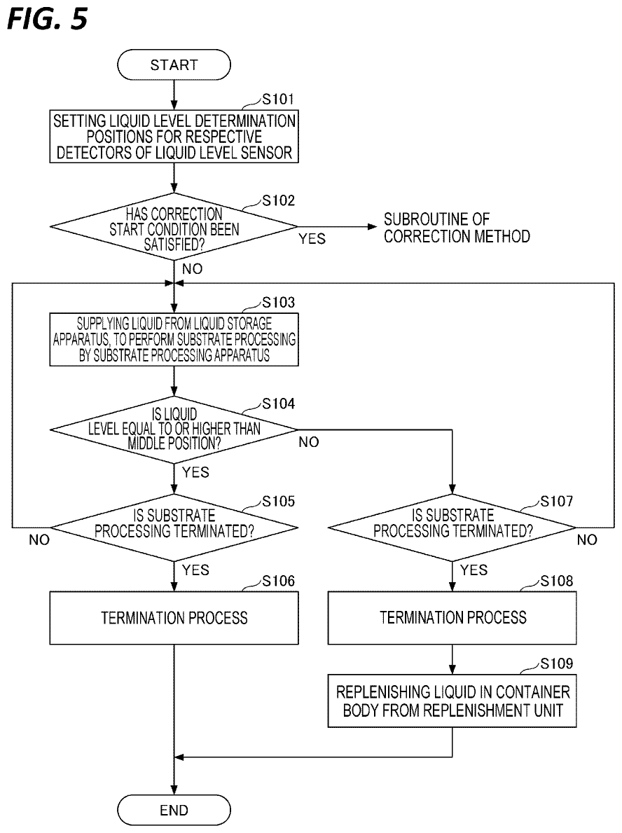

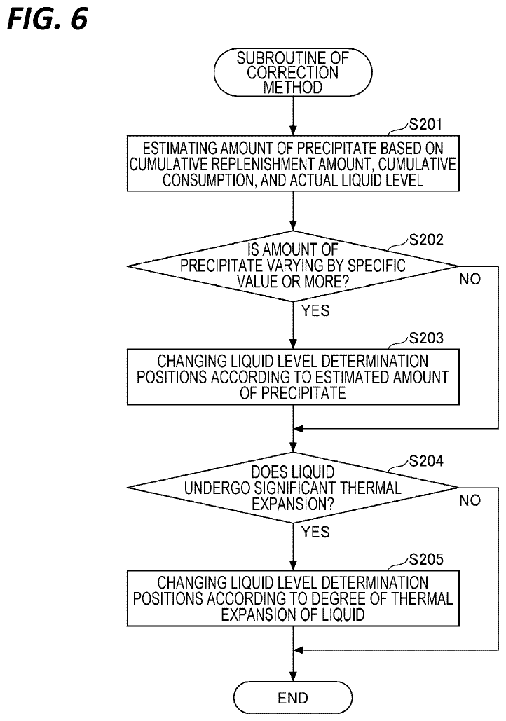

The liquid storage apparatus 10 and the semiconductor manufacturing system 1 according to the embodiment are basically configured as described above, and hereinafter, the operations thereof are described with reference to FIGS. 5 and 6. FIG. 5 is a flowchart illustrating a liquid replenishing method. FIG. 6 is a flowchart illustrating a method of correcting the liquid level determination position.

The controller 90 of the semiconductor manufacturing system 1 controls steps S101 to S109 illustrated in FIG. 5, to perform the substrate processing by the substrate processing apparatus 50 and manage the liquid of the liquid storage apparatus 10.

Specifically, prior to starting the substrate processing by the substrate processing apparatus 50, the controller 90 sets the liquid level determination positions (the highest position HP, the middle position MP, and the lowest position LP) corresponding to different detectors 21, respectively, among the detectors 21 of the liquid level sensor 20 (step S101). For example, the liquid level determination position setting unit 101 of the controller 90 sets the reference liquid level determination positions based on the contents of the substrate processing as described above.

Further, prior to starting the substrate processing, the liquid state estimation process unit 105 determines whether a correction start condition for performing a correction method to adjust the liquid level determination positions is satisfied (step S102). The correction start condition may include, for example, a case where the time period during which the substrate processing has been performed or the number of times of performing the substrate processing (e.g., the cumulative consumption of the liquid) is equal to or more than a preset threshold value, and a case where the liquid in the container body 11 is heated according to the substrate processing. When it is determined that the correction start condition is satisfied (step S102: YES), the controller 90 proceeds to the subroutine of the correction method. Meanwhile, when it is determined that the correction start condition is not satisfied (step S102: NO), the controller 90 does not perform the correction method at this time, and proceeds to step S103. The timing for determining the correction start condition is not limited to the timing prior to starting the substrate processing, but may be any appropriate timing such as the time when the liquid level of the container body 11 becomes lower than the middle position MP, after the end of the substrate processing. When the correction is performed at a timing other than the timing prior to starting the substrate processing, the controller 90 may store the corrected liquid level determination positions in the memory.

In step S103, the controller 90 controls the substrate processing apparatus 50 to perform the substrate processing, after performing, for example, the temperature adjustment of the liquid in the container body 11 according to the substrate processing (heating by the heating unit 19), and the adjustment of the pressure or temperature of the substrate processing apparatus 50. During the substrate processing, the liquid storage apparatus 10 supplies the liquid from the container body 11 to the substrate processing apparatus 50 through the supply network 30. As the substrate processing is progressed, the liquid level of the liquid in the container body 11 is gradually lowered.

The controller 90 monitors the liquid level of the liquid in the container body 11 by acquiring the detection information of the liquid level from the liquid level sensor 20 during the substrate processing, to determine whether the liquid level is equal to or higher than the middle position MP (step S104). When it is determined that the liquid level is equal to or higher than the middle position MP (step S104: YES), the process proceeds to step S105. In step S105, the controller 90 determines whether to terminate the substrate processing. When it is determined to continue the substrate processing (step S105: NO), the process returns to step S103 to repeat the same and subsequent steps. Meanwhile, when it is determined to terminate the substrate processing (step S105: YES), the process proceeds to step S106 to perform termination processes such as stopping the liquid supply by the liquid storage apparatus 10 and taking the substrate W out of the substrate processing apparatus 50, and terminate the substrate processing.

Meanwhile, when it is determined that the liquid level is lower than the middle position MP (step S104: NO), the controller 90 proceeds to step S107. In step S107, the controller 90 determines whether to terminate the substrate processing. When it is determined to continue the substrate processing (step S107: NO), the process returns to step S103 to repeat the same and subsequent steps. Meanwhile, when it is determined to terminate the substrate processing (step S107: YES), the process proceeds to step S108 to perform termination processes such as stopping the liquid supply by the liquid storage apparatus 10 and taking the substrate W out of the substrate processing apparatus 50, and terminate the substrate processing.

Further, the controller 90 replenishes the container body 11 with the liquid from the replenishment unit 15, based on the liquid level falling below the preset middle position MP (step S109). As a result, the container body 11 is replenished with the liquid exceeding the middle position MP, and the liquid storage apparatus 10 may stably supply the liquid for the next substrate processing.

When the correction start condition is satisfied in step S102 as described above, the controller 90 performs the subroutine of the correction method illustrated in FIG. 6 to correct the liquid level determination positions. For example, in the correction method, the liquid state estimation process unit 105 of the controller 90 first estimates the amount of precipitate being deposited in the container body 11 based on the cumulative replenishment amount, the cumulative consumption, and the actual liquid level as described above (step S201).

Next, the liquid state estimation process unit 105 determines whether the estimated amount of precipitate is varying by a specific value or more (step S202). In this case, the specific value is, for example, an amount at which the detectors 21 of the liquid level sensor 20 setting the liquid level determination positions needs to be shifted, and may be set in advance through experiments or simulations. The liquid state estimation process unit 105 proceeds to step S203 when it is determined that the amount of precipitate is varying by the specific value or more (step S202: YES), and proceeds to step S204, without performing step S203, when it is determined that the change of the amount of precipitate is less than the specific value (step S202: NO).

In step S203, the controller 90 changes the liquid level determination positions according to the estimated amount of precipitate. For example, when the detectors 21 deviate upwardly by only one step due to the amount of precipitate, the controller 90 performs the process of shifting each of the detectors 21 corresponding to the set liquid level determination positions (the highest position HP, the middle position MP, and the lowest position LP) upwardly by one step.

Further, the controller 90 determines whether the liquid undergoes a significant thermal expansion, when the temperature of the liquid in the container body 11 is changed through the heating by the heating unit 19 (step S204). For example, the controller 90 calculates the degree of expansion of the liquid when the temperature of the liquid is increased to the target temperature through the heating by the heating unit 19, based on, for example, the thermal expansion coefficient of the liquid, the target temperature, and the volume or cross-sectional area of the container body 11. The degree of expansion is an indicator of the change of the liquid along the height direction in the container body 11, and the liquid rises as the degree of expansion is significant. The controller 90 determines that the thermal expansion is significant when the degree of expansion of the liquid affects the positions of the detectors 21 of the liquid level sensor 20 (step S204: YES), and proceeds to step S205. Meanwhile, when it is determined that the thermal expansion is not significant (step S204: NO), step S205 is not performed. Further, when the thermal expansion coefficient of the liquid varies due to the change of the liquid stored in the container body 11, the controller 90 may also determine the thermal expansion of the liquid at this timing.

In step S205, the controller 90 changes the liquid level determination positions according to the degree of expansion of the liquid. For example, when the detectors 21 deviate upwardly by only one step due to the thermal expansion of the liquid, the controller 90 performs the process of shifting each of the detectors 21 corresponding to the set liquid level determination positions (the highest position HP, the middle position MP, and the lowest position LP) upwardly by one step. Further, the controller 90 may add the amount of change in height position of the liquid surface based on the amount of precipitate and the amount of change in height position of the liquid surface based on the thermal expansion, to calculate the total amount of change in liquid level of the liquid, and set the shift amount of the detectors 21.

With the correction method described above, the liquid storage apparatus 10 and the semiconductor manufacturing system 1 may correct the liquid level determination positions of the liquid level sensor 20 of the container body 11 again to appropriate detectors 21. After the correction, the controller 90 may return to step S103 of FIG. 5, to appropriately manage the liquid of the container body 11 based on the corrected liquid level determination positions in the substrate processing of the substrate processing apparatus 50.

The liquid storage apparatus 10, the semiconductor manufacturing system 1, and the correction method of the present disclosure are not limited to the first embodiment described above, and may include various modifications. For example, the semiconductor manufacturing system 1 may recognize the amount of liquid used for each substrate processing, to adjust the timing for replenishing the liquid in the container body 11 from the replenishment unit 15, or the supply amount (replenishment amount). For example, the semiconductor manufacturing system 1 may not perform the replenishment because of concerns that the temperature of the liquid may drop due to the replenishment while the substrate processing is being continuously performed. In this case, the controller 90 may set, in advance, the liquid level before the substrate processing to be high (increase the replenishment amount of liquid replenished from the replenishment unit 15), and set the middle position MP to be low, thereby reducing the number of times of the replenishment of the liquid.

Further, without being limited to the configuration where the liquid in the container body 11 is heated by the heating unit 19, the liquid storage apparatus 10 may be configured to lower the temperature of the liquid by circulating a coolant in the flow path formed in the container body 11, and a chiller. Even when the liquid level changes due to the drop of the temperature of the liquid, the liquid storage apparatus 10 may adjust the liquid level determination positions, to appropriately respond to the change in liquid level.

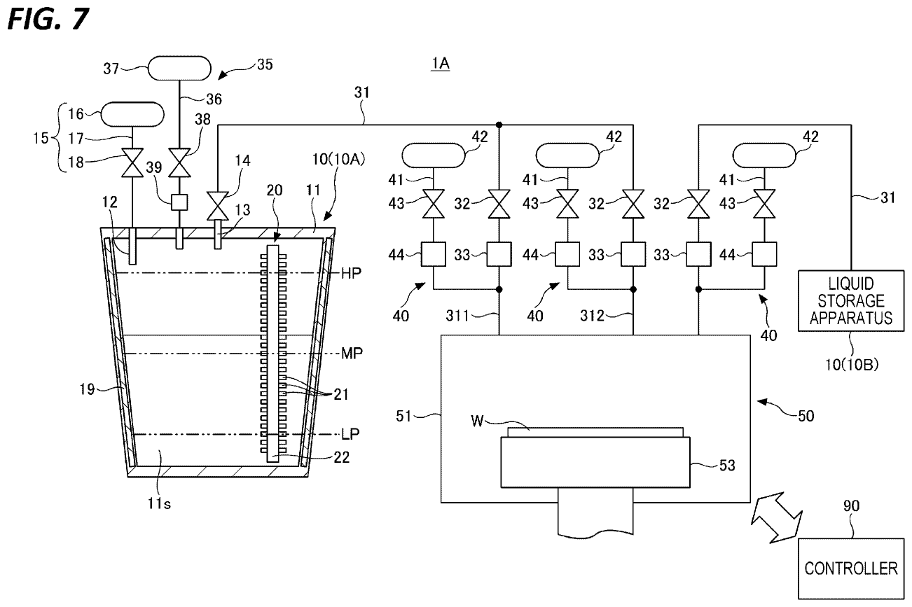

FIG. 7 is a view illustrating a semiconductor manufacturing system 1A according to a second embodiment. The semiconductor manufacturing system 1A according to the second embodiment is different from the semiconductor manufacturing system 1 described above in that a processing gas vaporized from the liquid of the liquid storage apparatus 10 is supplied to the substrate processing apparatus 50 through the supply network 30 to perform the substrate processing on the substrate W. The substrate processing includes, for example, a deposition process by an atomic layer deposition (ALD) or a molecular layer deposition (MLD). Hereinafter, the semiconductor manufacturing system 1 that performs the ALD is be described.

As in the first embodiment, the semiconductor manufacturing system 1A includes, for example, the liquid storage apparatus 10, the supply network 30, and the substrate processing apparatus 50. However, the outlet port 13 of the liquid storage apparatus 10 is attached to the ceiling of the container body 11, to transfer the processing gas vaporized from the liquid to the supply path 31 of the supply network 30. As for the liquid supplied to the substrate processing apparatus 50, an appropriate liquid may be used according to the contents of the substrate processing. For example, when a deposition process for depositing a silicon nitride film is performed, an applicable liquid may be tris(dimethylamino) silane SiH(N(CH₃)₂)₃, so-called 3DMAS.

The supply network 30 may include a carrier gas supply unit 35 that may supply a carrier gas to the storage space 11s of the container body 11. The carrier gas supply unit 35 may supply the carrier gas to the container body 11, to transfer the vaporized liquid together with the carrier gas from the container body 11 to the supply network 30. As the carrier gas, an inert gas such as N₂ gas or noble gas may be applied.

For example, the carrier gas supply unit 35 includes an inflow path 36 through which the carrier gas may be introduced into the container body 11, a carrier gas source 37 provided on the inflow path 36, an opening/closing valve 38, and a flow rate controller 39. By controlling the opening/closing valve 38 and the flow rate controller 39, the controller 90 supplies an appropriate amount of carrier gas from the carrier gas source 37 to the container body 11, and transfers the processing gas vaporized from the liquid by the carrier gas.

The substrate processing apparatus 50 includes a shower head (not illustrated) or the like, for example, at the top of the processing container 51, and substantially evenly distributes and supplies the processing gas supplied from the supply network 30 to the substrate W. As a result, a film based on the supplied processing gas is deposited on the surface of the substrate W. The substrate processing apparatus 50 may be configured to perform a plasma processing for generating a plasma in the processing gas.

In the semiconductor manufacturing system 1A of the second embodiment as well, the liquid level sensor 20 detects the liquid level of the liquid stored in the liquid storage apparatus 10 to manage, for example, the vaporization, supply, and replenishment of the liquid, as in the first embodiment. In particular, the liquid level sensor 20 includes a plurality of (four or more) detectors 21, and the controller 90 sets three or more liquid level determination positions for the detectors 21, respectively, and may adjust the liquid level determination positions. As a result, the semiconductor manufacturing system 1A may stably perform, for example, the supply of the liquid (processing gas) of the container body 11 and the replenishment of the liquid in the container body 11

The technical concepts and effects of the present disclosure described above in the embodiments are described below.

According to a first aspect of the present disclosure, a liquid storage apparatus 10 includes: a container body 11 storing a processing liquid for a substrate processing apparatus 50 therein; a liquid level sensor 20 provided in the container body 11 and detecting a liquid level of the stored processing liquid; a replenishment unit 15 replenishing the processing liquid in the container body 11; and a control unit (controller 90) acquiring detection information from the liquid level sensor 20 to perform a processing. The liquid level sensor 20 includes four or more detectors 21 capable of detecting the liquid level of the processing liquid along a height direction of the container body 11, and the controller 90 sets at least three liquid level determination positions corresponding to different detectors 21, respectively, among the four or more detectors 21, and controls a replenishment of the processing liquid in the container body 11 from the replenishment unit 15 based on detection information of the at least three set liquid level determination positions.

According to the configuration above, the liquid storage apparatus 10 may manage the liquid level of the processing liquid in the container body 11 with high precision, by using the liquid level sensor 20 including the four or more detectors 21. That is, the liquid storage apparatus 10 may detect the liquid levels at various height positions in the container body 11, by using the four or more detectors 21. Further, the liquid storage apparatus 10 may appropriately control, for example, the timings for the discharge of the processing liquid from the container body 11 (including the vaporization of the processing liquid) and the replenishment of the processing liquid in the container body 11, by making the at least three liquid level determination positions correspond to the detectors 21, respectively. Further, the liquid storage apparatus 10 may change the at least three liquid level determination positions for the four or more detectors 21, so that it is possible to set optimized liquid level determination positions according to the contents of the substrate processing or the state of the processing liquid in the container body 11.

The at least three liquid level determination positions include a middle liquid level determination position (middle position MP) sandwiched between the uppermost liquid level determination position (highest position HP) and the lowermost liquid level determination position (lowest position LP), and the control unit (controller 90) replenishes the processing liquid in the container body 11 from the replenishment unit 15 when the processing liquid falls below the middle liquid level determination position. As a result, the liquid storage apparatus 10 may easily perform the replenishment of the processing liquid in the container body 11.

Further, the control unit (controller 90) adjusts the middle liquid level determination position (middle position MP) based on the substrate processing of the substrate processing apparatus 50. As a result, the liquid storage apparatus 10 may stably supply the processing liquid in the amount corresponding to the substrate processing.

When the substrate processing is continuously performed, the control unit (controller 90) sets the middle liquid level determination position (middle position MP) to be lower than the preset position, and increases the replenishment amount of processing liquid replenished in the container body 11 from the replenishment unit 15. As a result, the liquid storage apparatus 10 may continuously perform the substrate processing without replenishing the processing liquid in the container body 11 in the middle of the substrate processing, which may improve the stabilization of the substrate processing.

The heating unit 19 is provided to heat the processing liquid stored in the container body 11, and the control unit (controller 90) adjusts the liquid level determination positions based on the target temperature of the processing liquid and the thermal expansion coefficient of the processing liquid. As a result, even when the thermal expansion occurs in the processing liquid due to the heating by the heating unit 19, the liquid storage apparatus 10 may appropriately manage the amount of processing liquid in the container body 11 by changing the liquid level determination positions.

The processing liquid contains a precipitate, and the control unit (controller 90) estimates the amount of precipitate to adjust the liquid level determination positions. As a result, even when a precipitate is deposited in the container body 11, the liquid storage apparatus 10 may appropriately manage the amount of processing liquid in the container body 11 by changing the liquid level determination positions.

The control unit (controller 90) estimates the amount of precipitate based on the cumulative replenishment amount of the processing liquid replenished in the container body 11. As a result, the liquid storage apparatus 10 may estimate the amount of precipitate deposited in the container body 11 with high precision.

Based on the estimated amount of precipitate, the control unit (controller 90) notifies a timing for replacing the container body 11. As a result, the liquid storage apparatus 10 may request the user to replace the container body 11 at an appropriate timing.

When the processing liquid in the container body 11 is replenished from the replenishment unit 15, the control unit (controller 90) changes the replenishment amount of processing liquid as time elapses, based on the detection information from the liquid level sensor 20. By changing the replenishment amount of processing liquid as time elapses, the liquid storage apparatus 10 may perform the replenishment of the liquid in a short time, and easily stabilize the liquid surface in the container body 11.

According to a second aspect of the present disclosure, a semiconductor manufacturing system 1 includes a liquid storage apparatus 10 that stores a processing liquid and a substrate processing apparatus 50 that performs a substrate processing on a substrate W using the processing liquid. The liquid storage apparatus 10 includes: a container body 11 storing the processing liquid therein; a liquid level sensor 20 provided in the container body 11, and detecting a liquid level of the stored processing liquid; a replenishment unit 15 replenishing the processing liquid in the container body 11; and a control unit (controller 90) acquiring detection information from the liquid level sensor 20 to perform a processing. The liquid level sensor 20 includes four or more detectors 21 capable of detecting the liquid level of the processing liquid along a height direction of the container body 11, and the control unit sets at least three liquid level determination positions corresponding to different detectors 21, respectively, among the four or more detectors 21, and controls a replenishment of the processing liquid in the container body 11 from the replenishment unit 15 based on the set at least three liquid level determination positions. As a result, the semiconductor manufacturing system 1 may control the liquid level of the processing liquid in the container body 11 with high precision.

According to a third aspect of the present disclosure, a liquid replenishing method includes: preparing a liquid storage apparatus 10 storing a processing liquid for a substrate processing apparatus 50 including a container body 11 storing the processing liquid therein, a liquid level sensor 20 provided in the container body 11 and detecting a liquid level of the stored processing liquid, and a replenishment unit 15 replenishing the processing liquid in the container body 11; setting at least three liquid level determination positions corresponding to different detectors 21, respectively, among four or more detectors 21 of the liquid level sensor 20 that are capable of detecting the liquid level of the processing liquid along a height direction of the container body 11; and replenishing the processing liquid in the container body 11 from the replenishment unit 15 based on detection information of the set at least three liquid level determination positions. In this case as well, the liquid replenishing method may control the liquid level of the processing liquid in the container body 11 with high precision.

The liquid storage apparatus 10, the semiconductor manufacturing system 1, and the replenishment method according to the embodiments described herein are merely examples in all aspects, and are not limited.

According to an aspect, the liquid level of a processing liquid stored in a container body may be controlled with high precision.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A liquid storage apparatus comprising:
a container configured to store a processing liquid for a substrate processing apparatus therein;
a liquid level sensor provided in the container, and configured to detect a liquid level of the processing liquid stored in the container,
a replenishment unit configured to replenish the processing liquid in the container; and
a controller configured to acquire detection information from the liquid level sensor, and perform a processing,
wherein the liquid level sensor includes four or more detectors capable of detecting the liquid level of the processing liquid along a height direction of the container, and
the controller sets at least three liquid level determination positions corresponding to different detectors, respectively, among the four or more detectors, and controls a replenishment of the processing liquid from the replenishment unit to the container based on detection information of the set at least three liquid level determination positions.

2. The liquid storage apparatus according to claim 1, wherein the at least three liquid level determination positions include a middle liquid level determination position sandwiched between an uppermost liquid level determination position and a lowermost liquid level determination position, and
when the processing liquid falls below the middle liquid level determination position, the controller replenishes the processing liquid in the container from the replenishment unit.

3. The liquid storage apparatus according to claim 2, wherein the controller adjusts the middle liquid level determination position based on a substrate processing by the substrate processing apparatus.

4. The liquid storage apparatus according to claim 3, wherein when the substrate processing is performed continuously, the controller sets the middle liquid level determination position to be lower than a preset position, and increases a replenishment amount of the processing liquid to be replenished in the container from the replenishment unit.

5. The liquid storage apparatus according to claim 1, further comprising:
a heater configured to heat the processing liquid stored in the container,
wherein the controller adjusts the liquid level determination positions based on a target temperature of the processing liquid and a thermal expansion coefficient of the processing liquid.

6. The liquid storage apparatus according to claim 1, wherein the processing liquid contains a precipitate, and
the controller adjusts the liquid level determination positions by estimating an amount of the precipitate.

7. The liquid storage apparatus according to claim 6, wherein the controller estimates the amount of the precipitate based on a cumulative replenishment amount of the processing liquid replenished in the container.

8. The liquid storage apparatus according to claim 6, wherein the controller notifies a timing for replacing the container based on the estimated amount of the precipitate.

9. The liquid storage apparatus according to claim 1, wherein when the processing liquid is replenished in the container from the replenishment unit, the controller changes a replenishment amount of the processing liquid as time elapses, based on the detection information from the liquid level sensor.

10. A semiconductor manufacturing system comprising:
a liquid storage apparatus that stores a processing liquid; and
a substrate processing apparatus that performs a substrate processing on a substrate using the processing liquid;
wherein the liquid storage apparatus includes
a container configured to store the processing liquid therein,
a liquid level sensor provided in the container, and configured to detect a liquid level of the processing liquid stored in the container;
a replenishment unit including a valve configured to replenish the processing liquid in the container; and
a controller configured to acquire detection information from the liquid level sensor, and perform a processing,
the liquid level sensor includes four or more detectors capable of detecting the liquid level of the processing liquid along a height direction of the container, and
the controller sets at least three liquid level determination positions corresponding to different detectors, respectively, among the four or more detectors, and controls a replenishment of the processing liquid in the container from the replenishment unit based on the set at least three liquid level determination positions.

11. A liquid replenishing method comprising:
providing a liquid storage apparatus that stores a processing liquid for a substrate processing apparatus including
a container configured to store the processing liquid therein,
a liquid level sensor provided in the container, and configured to detect a liquid level of the processing liquid stored in the container, and
a replenishment unit including a valve configured to replenish the processing liquid in the container;
setting at least three liquid level determination positions corresponding to different detectors, respectively, among four or more detectors of the liquid level sensor that are capable of detecting the liquid level of the processing liquid along a height direction of the container; and
replenishing the processing liquid in the container from the replenishment unit based on detection information of the at least three liquid level determination positions set in the setting.
